(19) United States
(12) Patent Application Publication
(10) Pub. No.: US 2007/0222035 A1
(43) Pub. Date: Sep. 27, 2007

(54) Stress intermedium engineering

(75) Inventors: Chien-Chao Huang, Hsin-Chu (TW); Fu-Liang Yang, Hsin-Chu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/387,601

(22) Filed: Mar. 23, 2006

(51) Int. Cl. H01L 29/06

(52) U.S. Cl. 257/618

(57) ABSTRACT

Embodiments of the invention provide structures and methods for forming a strained MOS transistor. A stressor layer is formed over the transistor. Embodiments include an intermedium layer between the stressor layer and a portion of the transistor. In an embodiment, the intermedium comprises a layer formed between the stressor layer and the gate electrode sidewall spacers. In another embodiment, the intermedium comprises a silicided portion of the substrate formed over the LDS/LDD regions. A transistor that includes the intermedium and, stressor layer has a vertically oriented stress within the channel region. The vertically oriented stress is tensile in a PMOS transistor and compressive in an NMOS transistor.

### TECHNICAL FIELD

This invention relates generally to semiconductor devices, and more particularly, to methods and structures for controlling strain in transistors to improve device performance.

### BACKGROUND

One way to improve transistor performance is through selective application of stress to the transistor channel region. Stress distorts (i.e., strains) the semiconductor crystal lattice, and the distortion in turn affects the band alignment and charge transport properties of the semiconductor. By controlling both the magnitude and distribution of stress in a finished device, manufacturers can increase carrier mobility and improve device performance. There are several approaches for straining the transistor channel region. The details concerning the effects of stress and strain on transistor performance are described in a publication by C. H. Ge et al. in Process-Strained Si (PSS) CMOS Technology Featuring 3D Strain Engineering, Electron Devices Meeting, Dec. 8-10, 2003, IEDM Technical Digest, IEEE International, which publication is incorporated by reference in its entirety.

One problem facing CMOS manufacturing is that NMOS and PMOS devices require different types of stress in order to achieve increased carrier mobility. FIG. 1a shows a conventional MOS transistor 81. In a substrate 87 are formed a source 83 and a drain 85, which are oppositely adjacent a gate electrode 90. For purposes of illustration, the x-axis is aligned in a source 83 to drain 85 direction. FIG. 1b summarizes the effect of increasing tensile strain (or decreasing compressive strain) on carrier mobility.

For example, a biaxial, tensile stress in the source/drain direction increases NMOS performance approximately twofold. However, for a PMOS device, such a stress yields almost no improvement. With a PMOS device, a tensile stress improves performance when it is perpendicular to the channel (y-direction), but it has nearly the opposite effect when it is parallel to the channel α-direction). Therefore, when a biaxial, tensile film is formed over a PMOS device, the two stress effects almost cancel each other out.

Another problem facing CMOS manufacturing is that conventional stressors are most effective in creating channel strain only within the plane of the substrate. Workers in the art are aware, however, that channel strain perpendicular to the plane of the substrate also affects NMOS in PMOS performance. For an NMOS transistor, a compressive stress applied to the channel region perpendicular to the plane of the substrate, improves device performance. For a PMOS transistor, on the other hand, a similarly oriented tensile stress improves device performance.

A problem with conventional strain engineering approaches is that they fail to effectively induce and/or modulate strain in the vertical direction. In light of the importance of strain engineering in semiconductor manufacturing there remains a need for improved methods and structures for controlling stress and strain in semiconductor devices.

### SUMMARY OF THE INVENTION

These and other problems are generally reduced, solved or circumvented, and technical advantages are generally achieved, by embodiments of the invention that provide methods and structures for forming strained transistors.

An embodiment of the invention provides a method of forming a MOS transistor. Embodiments comprise forming a gate electrode on a substrate, and forming a lightly doped source/drain (LDS/LDD) region in the substrate by an ion implantation using the gate electrode as a mask. Sidewall spacers are formed along the gate electrode. Embodiments include forming a source/drain region in the substrate using the gate electrode and the gate spacers as a mask. A channel region under the gate electrode lies between the LDS/LDD regions.

In preferred embodiments of the invention, the transistor further includes a stressor. In an embodiment, the stressor comprises a stressor layer formed over the transistor. Preferred embodiments of the invention further include an intermedium between the stressor and a portion of the transistor. In an embodiment, the intermedium comprises a layer formed between the tensile layer and the gate sidewall spacers. In another embodiment, the intermedium comprises a silicided portion of the substrate. Preferably, the silicided portion is formed between the tensile layer and the LDS/LDD regions.

Preferably, the intermedium comprises a material having a low Young's modulus, E, (also called a tensile modulus) and/or a large Poisson's ratio, υ. In an embodiment, the Young's modulus is about 100 GPa, and the Poisson's ratio is about 0.33. By way of example, suitable intermedium materials comprise Si, SiON, silicon carbide, silicon nitride, nickel silicide, or cobalt silicide.

An embodiment includes creating a vertically oriented tensile strain in the channel region of a PMOS transistor. Another embodiment includes creating a vertically oriented compressive strain in the channel region of an NMOS transistor.

In another embodiment, the Poisson's ratio greater than about 0.25, and the Young's modulus less than about 200 GPa. Embodiments preferably include a stressor layer has an intrinsic stress (compressive or tensile) between about 500 MPa and about 3 GPa. The intermedium layer may comprise a material such as a nitride, a carbide, a silicide, and combinations thereof. The stressor layer may comprise a material such as silicon nitride, silicon carbide, silicon oxide, nitrided silicon oxide (SiON), silicon germanium, and combinations thereof. Suitable substrates include silicon, silicon germanium, or combinations thereof.

Note that although the term layer is used throughout the specification and in the claims, the resulting features formed using the layer should not be interpreted together as only a continuous or uninterrupted feature. As will be clear from reading the specification, the layer may be separated into distinct and isolated features (e.g., active regions), some or all of which comprise portions of the semiconductor layer. In other embodiments, a layer may refer to a continuous feature having a uniform appearance; yet, it may include regions having different physical or chemical properties.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a and 1b show the stress effects on a MOS device according to the prior art;

FIGS. 2a-2c show the stress effects of an intermedium layer between a blanket stressor and a substrate according to an embodiment of the invention;

FIG. 3 is a cross-sectional view of a partially completed MOS transistor according to an embodiment of the invention;

FIGS. 4a-4c are cross-sectional views of an intermedium region in source/drain regions according to alternative embodiments of the invention;

FIG. 5a cross-sectional view of a multi-layer spacer and an intermedium region according to an embodiment of the invention

FIG. 5b is a graph of the normal stress components corresponding to the embodiment of FIG. 5a;

FIG. 6a is a cross-sectional view of an alternative embodiment of the invention; and

FIG. 6b is a graph of the normal stresses corresponding to the embodiment of FIG. 6a.

Corresponding numerals and symbols in the different figures generally refer to corresponding parts unless otherwise indicated. The figures are drawn to clearly illustrate the relevant aspects of the preferred embodiments and are not necessarily drawn to scale. To more clearly illustrate certain embodiments, a letter or symbol indicating variations of the same structure, material, or process step may follow a figure number.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

This invention relates generally to semiconductor device fabrication and more particularly to structures and methods for strained transistors. This invention will now be described with respect to preferred embodiments in a specific context, namely the creation of MOS and CMOS devices. Embodiments of this invention are believed to be particularly advantageous when used in this process. It is also believed that embodiments described herein will benefit other applications not specifically mentioned. Therefore, the specific embodiments discussed, including exemplary parameter values and ranges of values, are merely illustrative of specific ways to make and use the invention, and do not limit the scope of the invention.

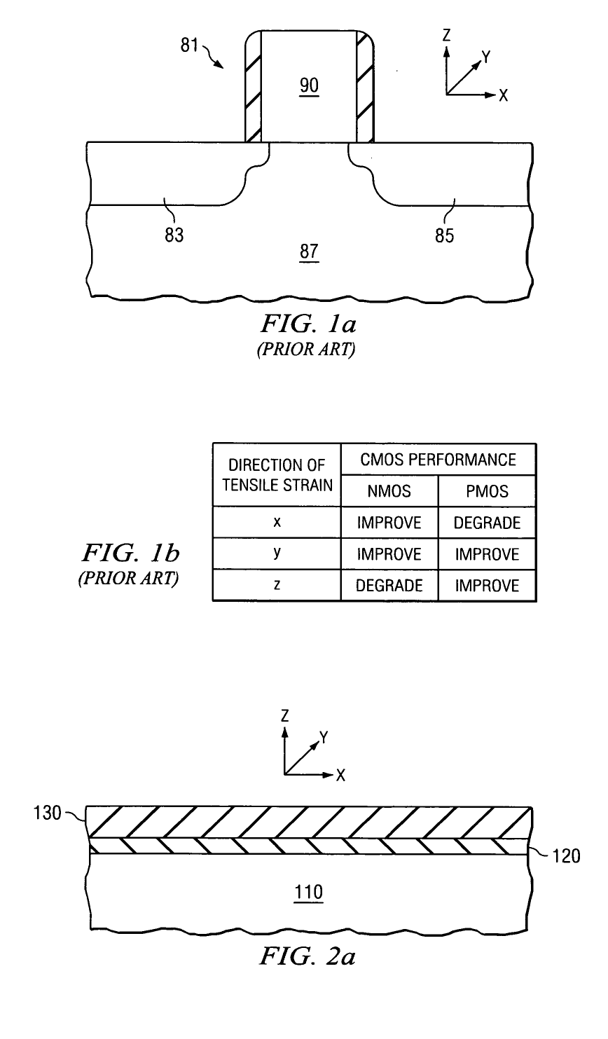

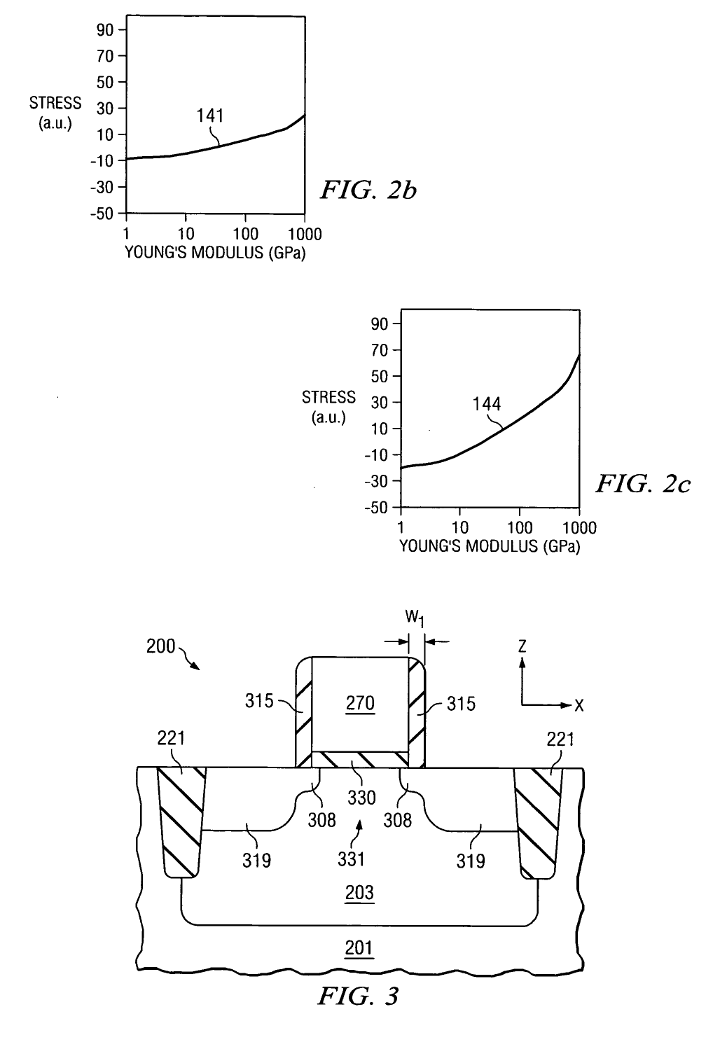

In FIG. 2a, there is schematically shown a semiconductor substrate 110. The substrate 110 may comprise bulk silicon, doped or undoped, or an active layer of a silicon on insulator (SOI) substrate. Generally, an SOI substrate comprises a layer of a semiconductor material such as silicon, germanium, silicon germanium, silicon on insulator (SOI), silicon germanium on insulator (SGOI), or combinations thereof. The insulator layer may be, for example, a buried oxide (BOX) layer or a silicon oxide layer. The insulator layer is provided on a substrate, typically a silicon or glass substrate. Other substrates that may be used include multi-layered substrates, gradient substrates, or hybrid orientation substrates.

Formed over the substrate 110 is a layer, which is referred to herein as an intermedium layer 120, over the intermedium layer 120 is a stressor 130. The stressor 130 may comprise a strain-inducing layer suitable for use in advanced semiconductor devices. The stressor 130 is preferably about 200 Å to about 1000 Å thick. The stressor 130 preferably comprises a compressive stress layer, although in other embodiments it comprises a tensile stress layer. A process used to form the stress layer 130 may include plasma enhanced chemical vapor deposition (PECVD), low pressure chemical vapor deposition (LPCVD), atomic layer deposition (ALD), rapid thermal chemical vapor deposition (RTCVD), physical vapor deposition (PVD), individually or in combination.

In an embodiment, the stressor 130 comprises a contact etch stop layer, such as silicon nitride. Stoichiometric silicon nitride films are known to be highly tensile stressed on silicon. However, the tensile stress may be greatly lowered and even turned into compressive stress by adjusting the Si/N ratio. Generally, adding more silicon makes the silicon nitride film more compressive, while adding more nitrogen makes it more tensile. For example, the intrinsic stress of silicon nitride on silicon is preferably adjusted from about 300 MPa to about 1700 MPa by adjusting the Si/N ratio. Stress levels between about −5.0 GPa to about +5.0 GPa, and beyond, are within the scope of embodiments of the invention.

The stressor 130 when compressive is preferably comprised of silicon nitride (Si₃N₄ or SiNₓ), silicon oxynitride (SiON), oxide, a Si-rich nitride, or a N-rich nitride. The compressive stressor 130 is more preferably SiN or SiON and is most preferably SiON. It has a thickness from about 200 Å to about 1000 Å, and preferably from about 250 Å to about 500 Å. The stressor 130 is preferably deposited by plasma enhanced chemical vapor deposition (PECVD). PECVD conditions include a temperature about 300° C. to about 600° C. Deposition time is about 10 seconds to about 500 seconds and preferably from about 20 seconds to about 120 seconds. The reactant NH₃:SiH₄ gas ratio is about 4:1 to about 10:1, and preferably less than about 8:1. Alternative reactants include a di-saline:NH₃ gas ratio from about 1:4 to about 1:10, and preferably less than about 1:1. The deposition pressure is preferably about 1.0 Torr to about 1.5 Torr. The PECVD power used to form the compressive stressor 130 is preferably from about 1000 W to 2000 W and more preferably greater than about 1000 W.

In alternative embodiments, the stressor 130 is a tensile stressor 130. When the stressor 130 is a tensile stress layer, suitable materials include, silicon nitride, tetraethylortho-silicate (TEOS), silicon oxynitride (SiON), oxide, Si-rich nitride, or a N-rich nitride, and it is preferably SiN or SiON. The tensile stressor 130 has a thickness from about 200 Å to about 1000 Å, and preferably from about 250 to about 500 Å. The tensile stressor 130 is preferably deposited by rapid thermal chemical vapor deposition (RTCVD). The RTCVD temperature is 350° C. to about 800° C., and preferably from about 400° C. to about 700° C. Reaction time is about 10 seconds to about 2000 seconds, and preferably about 20 seconds to about 120 seconds. The NH3:SiH4 gas ratio is about 50:1 to about 400:1, and preferably less than about 700:1. An alternative reactant composition includes a di-saline:NH3 gas ratio about 1:40 to about 1:500, and preferably less than about 1:1. The deposition pressure is preferably about 10 Torr to about 400 Torr, preferably less than about 300 Torr.

Continuing with FIG. 2a, preferred embodiments of the invention further include an intermedium layer 120 formed between the substrate 110 and the stressor 130. The intermedium layer 120 preferably controls, or modulates, the transfer of stress and strain from the stressor 130 to the substrate 110.

FIG. 2a further illustrates the orientation of the axis used to describe embodiments of the invention. The z-axis is perpendicular to the surface of the substrate and lies within the plane of the paper. In other words, if the substrate were to have a (100) crystallographic surface orientation, the z-axis would lie parallel to the [100] direction, as this direction is perpendicular to the substrate's surface. For purposes of discussion, the z-axis orientation may be referred to as the vertical direction. The x-axis is parallel to the surface of the substrate and lies within the plane of the paper. Were a transistor fabricated on the substrate 110, a suitable channel orientation may be along the x-axis, or the [110] crystallographic direction. The y-axis is parallel to the surface of the substrate 110 and is perpendicular to the x-axis.

Continuing with FIG. 2a, the intermedium layer 120 of preferred embodiments is particularly advantageous in modulating stress in the vertical direction. In an embodiment of the invention, the intermedium layer 120 is preferably about 450 Å thick. Applicants have found that intermedium materials having a low Young's modulus, E, (also called tensile modulus) and materials having a low Poisson's ratio, υ, are particularly preferred intermedium materials.

In an embodiment, the intermedium layer 120 comprises amorphous silicon carbide (a-SiₓC₁₋ₓ). When x is about 0.5, the Young's modulus of a-SiₓC₁₋ₓ is about 150 GPa, and the Poisson's ratio is about 0.2. Most preferably, the Young's modulus of the intermedium layer 120 is less than about 400 GPa. The silicon carbide may be deposited at about 800° C. It may also comprise a hydrogenated film in addition to, or instead of, an amorphous film. In another embodiment, the intermedium layer 120 may comprise PECVD SiON. Other intermedium materials include: Si, E=187 GPa, υ=0.28; NiSi, E=132 GPa, υ=0.33; CoSi₂, E=114 GPa, υ=0.33.

Shown in FIGS. 2b and 2c are calculated values of the principal stress components σₓₓ 141 and σ_{zz} 144, respectively, for the blanket film intermedium layer 120 arrangement of FIG. 2a. The stressor layer 130 is a conventional high tensile stress cap film. The values of σₓₓ 141 and σ_{zz} 144 are calculated at the surface of the substrate 110 as a function of Young's modulus of the intermedium layer 120.

In keeping with conventional nomenclature, positive stress values are tensile, and negative stress values are compressive. One skilled in the art understands that were the intermedium layer not present, a tensile stressor would create a compressive stress at the surface region of the underlying substrate. Likewise, a compressive stressor layer would create a tensile stress at the surface region of the underlying substrate. Also known to those in the art is that the x-direction mobility of NMOS channel is improved by channel tensile stress, but the z-direction mobility of NMOS channel is improved by channel compressive stress.

As shown in these figures, including an intermedium layer between a stressor layer and a substrate is an efficient method for modulating stress in semiconductors. For example, by selecting an intermedium with the correct Young's Modulus and selectively depositing that material it is possible to convert a region underlying a stressor from tensile to compressive and vice versa. It is also possible to decouple a portion of the substrate from the stressor layer so that a portion of the substrate is essentially stress free, i.e. σ=0. Briefly, the intermedium layer affects the stress transfer efficiency between the stressor and the substrate, and more particularly, between the stressor and the MOSFET channel region.

Alternative embodiments of the invention are now illustrated within the exemplary context of a conventional MOS transistor 200 such as that illustrated in FIG. 3. A silicon substrate 201 preferably comprises a p-doped, (100) silicon wafer. The substrate 201 includes an active region 203 suitable for forming semiconductor devices. The active region may further include a doped well region, which is of opposite P or N polarity than the substrate 201. The relative orientation of the x-axis and z-axis, which are referenced in describing the principal stress components below, are also shown. The x-axis is parallel with the source-to-drain direction, and z-axis is perpendicular to the surface of substrate 201.

An isolation structure, such as a shallow trench isolation (STI) region 221, may be formed within the substrate 201 to isolate active region 203 from other device fabrication regions in the substrate 201. The STI regions 221 are formed using conventional thermal growth methods and isolation region deposition and patterning methods. Formed over the active region 203 is a gate dielectric layer 230. The gate dielectric 330 may include a thermally grown silicon oxide having a thickness from about 5 Å to about 100 Å, and more preferably less than about 20 Å. In other embodiments, the gate dielectric 330 may include a high-k dielectric having a k-value greater than about 4 and may include, for example, hafnium-based materials such as HfO₂, HfSiOₓ, HfAlOₓ.

A gate electrode 270 is formed over the gate dielectric 330 layer. The gate electrode 270 may comprise metals, metal alloys, metal-containing materials, polysilicon, polysilicon, and polycide (doped polysilicon/metal silicide stack) gate electrode materials. Preferably, the gate electrode 270 comprises chemical vapor deposition (CVD) polysilicon between about 100 Å and about 10,000 Å thick and more preferably between about 500 Å and about 2,000 Å. The gate electrode 270 may further include about 1*10²⁰ cm⁻³ dopant of polarity opposite the channel region of the corresponding MOS device to be formed therefrom. Such doping advantageously provides for enhanced off current (Ioff) performance, enhanced drain saturation current (Idsat) performance and possibly enhanced short channel effect (SCE) performance of the PMOS device.

An optional glue layer (not illustrated) maybe is formed between the gate dielectric layer 230 and the gate electrode 270. The glue layer promotes adhesion between adjacent layers. It may be formed by CVD of poly silicon, amorphous silicon, TiN, Ti, Ta, TaN, or combinations thereof.

Using the gate electrodes 270 as a mask lightly doped source/drain (LDS/LDD) regions 308 are formed in the substrate 201 to a depth between about 100 Å and about 1000 Å and preferably between about 200 Å and about 400 Å. An LDS/LDD region 308 is formed by ion implanting a dopant such as boron or phosphorous. After annealing the concentration of phosphorus or arsenic dopant in the LDS/LDD regions 308 is preferably between about 5*10¹⁶ atoms/cm³ to about 1*10¹⁹ atoms/cm³.

Between the LDS/LDD regions 308 and under the gate electrode there is a channel region 331. Formed on sidewalls of the gate electrode 270 are sidewall spacers 315. The sidewall spacers 315 are a dielectric, such as CVD silicon oxide. Using the gate electrodes 270 and also sidewall spacers 315 as a mask, heavily doped source/drain 319 regions are formed. The sidewall spacers 315 have a first thickness indicated by w₁ in FIG. 3. The source/drain regions 319 may extend below the LDS/LDD regions 308. After annealing, the concentration of dopants in the regions 319 is preferably between about 5*10¹⁸ atoms/cm³ and about 5*10²⁰ atoms/cm³.

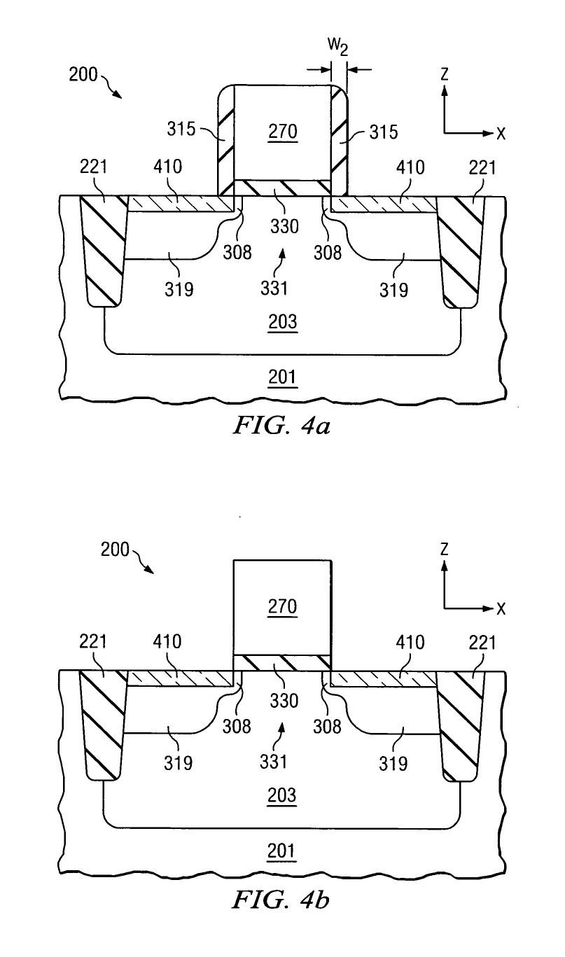

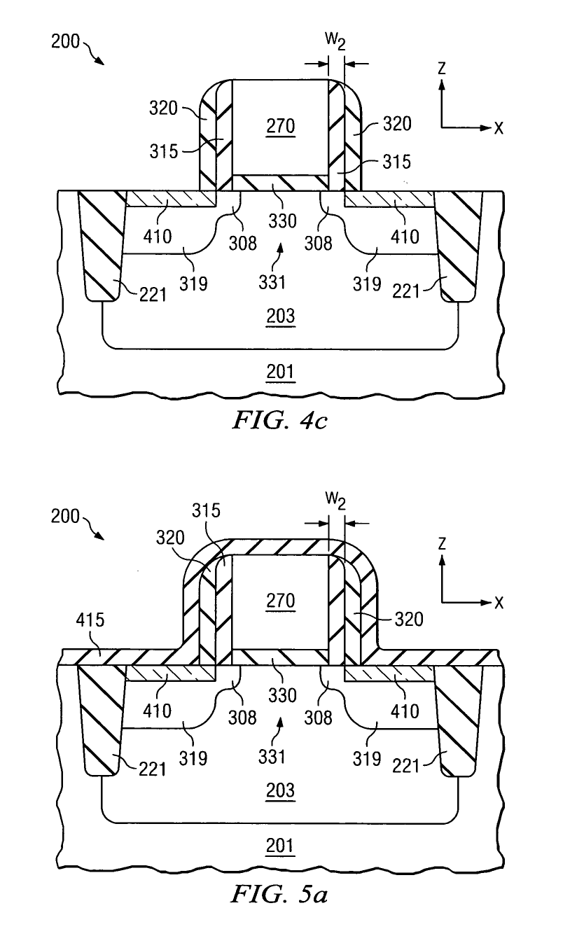

Turning now to FIG. 4a there is illustrated the MOS transistor 200 of FIG. 3, wherein the MOS transistor 200 further comprises stress intermedium engineering according to a first alternative embodiment of the invention.

Formed over the MOS transistor is a stressor layer 415, which preferably comprises tensile silicon nitride. To modulate stress in the channel region 331, a silicide intermedium region 410 is formed within the source/drain regions 319 and optionally within the LDS/LDD regions 308 in a surface region the substrate 201. Again, the intermedium serves to modulate the stress in the channel region 331 induced by a subsequently formed stressor layer. The silicide intermedium region 410 may be formed using the spacers 315 as an implant mask. The depth of the intermedium region 410 is preferably less than about 200 Å.

The lateral extent of the intermedium region 410 with respect to the LDS/LDD regions 308 is optionally adjusted by thinning the sidewall spacer 315 to a second width, w₂ before forming the intermedium region 410. The second width may be between the first width, w₁, and zero, i.e., w₁≦w₂≦0. In the embodiment illustrated in FIG. 4a, the second width is preferably less than about 300 Å. An alternative embodiment in FIG. 4b illustrates the intermedium region 410 when the spacer width is essentially zero and the gate electrode 270 serves as an intermedium-forming mask. In this embodiment, the intermedium region 410 is formed within the LDS/LDD 308 of the substrate 201, proximate the gate electrode 270.

Embodiments of the invention may include other process steps or structures for modulating the effect of a subsequently to be formed stressor layer on the channel region 331. For example, FIG. 4c shows the structure of FIG. 4a after forming a second sidewall spacer 320 on the first sidewall spacer 315. These two spacers may conveniently be referred to as a multilayer sidewall spacer. The process sequence leading to FIG. 4c advantageously allows for the intermedium region 410 to optionally underlie a portion of the multilayer sidewall spacer. The total width of the multilayer sidewall spacer of FIG. 4c is preferably less than about 500 Å.

Embodiments having a silicide intermedium layer 410 on the LDS/LDD regions 308 are summarized in FIGS. 4a and 4b. These figures indicate that a tensile stressor layer 415 formed over a MOS transistor 200 on a (1,0,0), (1,1,0), (1,1,1)-oriented substrate 201 induces a tensile stress perpendicular to the surface of the substrate 201. As one skilled in the art will recognize after reading this disclosure, such a configuration is preferred for a PMOS device. Alternatively, a compressive stressor layer 415 induces a compressive stress perpendicular the surface of the substrate 201. On skilled in the art recognizes that such a configuration is preferred for a NMOS transistor fabricated on a (100) wafer.

The intermedium layer 410 when a silicide may be a single layer or a plurality of layers of a silicidation metal comprising, for example, nickel, cobalt, copper, molybdenum, titanium, tantalum, tungsten, erbium, zirconium, platinum, or a combination thereof, but more preferably, comprises nickel or cobalt. The silicide intermedium layer 410 may be formed using deposition techniques such as, for example, evaporation, sputter deposition, chemical vapor deposition (CVD). The viscosity of intermedium layer 410 is preferably larger than about 1*10¹⁵ Pa·s above 200° C.

The silicidation process preferably includes annealing at about 300° C. to about 1100° C. for about 0.1 seconds to about 300 seconds in an inert ambient such as nitrogen or argon. An optional RTA process may also be performed to further lower the phase to a low-resistivity silicide. For example, CoSi₂ benefits from an additional rapid thermal anneal at about 300° C. to about 1100° C. for about 0.1 seconds to about 300 seconds. Any excess metal may be removed using an etchant such as H₂SO₄, HCl, H₂O₂, or NH₄OH.

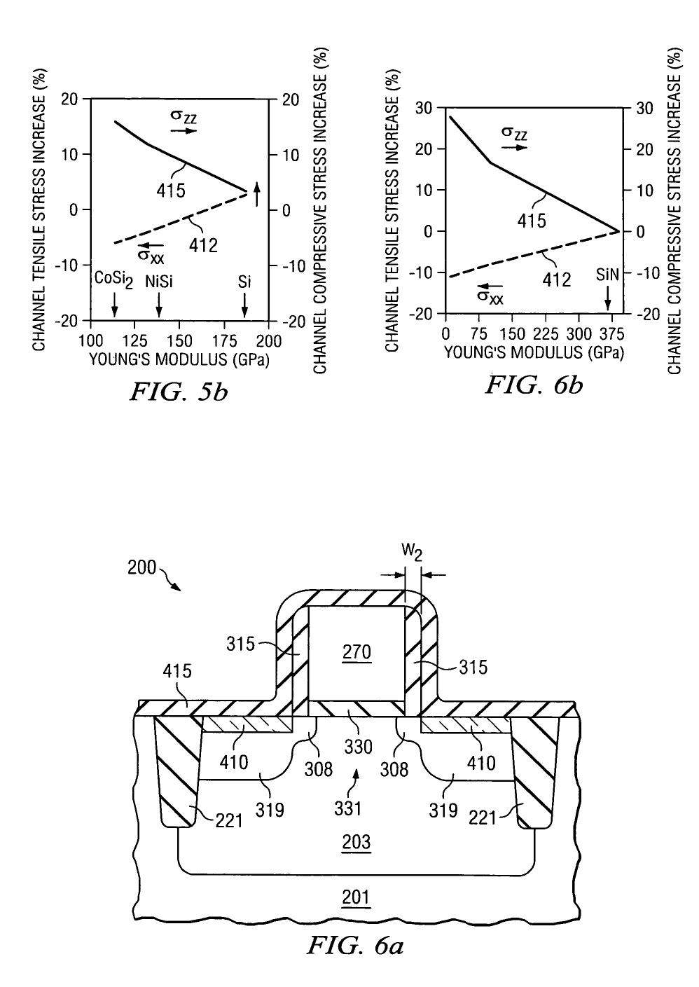

Turning now to FIG. 5a there is illustrated the MOS transistor 200 of FIG. 4c after forming a stressor layer 415 over the transistor. The stressor layer 415 may formed as provided above in connection with FIG. 2a.

Plotted in FIG. 5b is a first curve 412 showing percent increase in σₓₓ tensile channel stress vs. Young's modulus of the intermedium layer (υ=0.33). A second curve 413 is a plot of percent increase in σ_{zz} compressive channel stress vs. Young's modulus of the intermedium layer. According to FIG. 5b, the lateral (x-axis) tensile channel stress decreases as Young's modulus decreases. While this is normally associated with decreased NMOS performance, the greater increase in the vertically-oriented (z-axis) compressive stress more than compensates for this decrease.

FIGS. 5a and 5b show that the intermedium arrangement of FIG. 5a has a net effect of increasing vertical channel stress. Therefore, this embodiment of the invention is preferred for an NMOSFET because a vertical channel compressive stress is associated with improved performance (or vertical tensile stress degrades performance).

Turning now to FIG. 6a, there is an alternative embodiment of the invention for improving NMOS performance. In FIG. 6a, there is a MOS transistor 200 formed according to the intermedium embodiment illustrated in FIG. 4a. FIG. 6b is a plot illustrating the interaction between stress aligned parallel to the channel region 331, σₓₓ (channel stress 412), and stress aligned perpendicular to the surface of the substrate 201, σ_{zz} (vertical stress 415). FIG. 6b corresponds to the embodiment illustrated in FIG. 6a.

As with FIG. 5b, FIG. 6b shows the effect of the first curve 412 showing percent increase in σₓₓ tensile channel stress vs. Young's modulus of the intermedium layer (υ=0.3). The second curve 415 is a plot of percent increase in σ_{zz} compressive channel stress vs. Young's modulus of the intermedium layer. According to FIG. 6b, the lateral (x-axis) tensile channel stress decreases as Young's modulus decreases. While this is normally associated with decreased NMOS performance, the greater increase in the vertically-oriented (z-axis) compressive stress more than compensates for this decrease.

To summarize, a stressor layer 415 formed over a MOS transistor 200 induces a three-dimensional, anisotropic stress/strain field in the channel region 331. Whether one or both of the principal normal stresses, σₓₓ and σ_{yy}, are compressive or tensile depends upon a complex interaction between the stressor layer 415, the silicide intermedium region 410, and location within the substrate 201. As described above, the stressor layer may comprise a component of a semiconductor structure. Preferably, there is a second layer, an intermedium layer, between the semiconductor substrate and the stressor layer. In an embodiment, the second layer comprises a silicide overlying an LDS/LDD region. The second layer may also comprise a material having a Poisson's ratio greater than about 0.25 and/or a Young's modulus less than about 200 GPa. The second layer may be a nitride, a carbide, a silicide, or combinations thereof. Preferably, second layer has a viscosity larger than about 1*10¹⁵ Pa·s. More preferably, the viscosity larger than about 1*10¹⁵ Pa·s above about 200° C.

In a preferred embodiment, transistor is a P-MOSFET and the stressor layer comprises a material having an intrinsic tensile stress. With the P-MOSFET, the stressor layer induces a first and a second stress in the substrate under the gate electrode, wherein the first stress is a compressive stress aligned substantially parallel to a surface of the substrate, and wherein the second stress is a tensile stress aligned substantially perpendicular to the surface of the substrate. In an alternative preferred embodiment, the transistor is an N-MOSFET and the stressor layer comprises a material having an intrinsic compressive stress. With the N-MOSFET, the stressor layer induces a first and a second stress in the substrate under the gate electrode, wherein the first stress is a tensile stress aligned substantially parallel to a surface of the substrate, and wherein the second stress is a compressive stress aligned substantially perpendicular to the surface of the substrate.

In still other alternative embodiments (not illustrated), the channel/substrate orientation may be selected with a view towards optimizing the appropriate charge carrier mobility using SOI or SGOI hybrid orientation substrates. For example, an NMOS channel may be oriented along the <100> direction, which is the direction of maximum electron mobility for a {100} substrate. Alternatively, a PMOS channel may be oriented along the <110> direction, which is the direction where hole mobility is maximum for a {110} substrate.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor structure comprising:
a stressor layer over a semiconductor substrate; and
a second layer between the semiconductor substrate and the stressor layer, wherein the second layer comprises a material having a Poisson's ratio greater than about 0.25.

2. The semiconductor structure of claim 1, wherein the second layer comprises a material having a Young's modulus less than about 200 GPa.

3. The semiconductor structure of claim 1, wherein the stressor layer has an intrinsic compressive stress between about 500 MPa and 3 GPa.

4. The semiconductor structure of claim 1, wherein the stressor layer has an intrinsic tensile stress between about 500 MPa and 3 GPa.

5. The semiconductor structure of claim 1, wherein the second layer comprises a material selected from the group consisting essentially a nitride, a carbide, a silicide, and combinations thereof.

6. The semiconductor structure of claim 1, wherein the stressor layer comprises a material selected from the group consisting essentially of a silicon nitride, silicon carbide, silicon oxide, nitrided silicon oxide (SiON), silicon germanium, and combinations thereof.

7. The semiconductor structure of claim 1, wherein the substrate comprises a material selected from the group consisting essentially of silicon, silicon germanium, or combinations thereof.

8. The semiconductor structure of claim 1, wherein the second layer comprises a material having a viscosity larger than about 1*10¹⁵ Pa·s.

9. The semiconductor structure of claim 1, wherein the second layer comprises a material having a viscosity larger than about 1*10¹⁵ Pa·s above a temperature of about 200° C.

10. A metal oxide semiconductor (MOS) transistor comprising:
a gate electrode on a substrate;
a lightly doped source/drain (LDS/LDD) region in the substrate adjacent the gate electrode;
a silicide region in the substrate over the LDS/LDD region;
a pair of spacers on sidewalls of the gate electrode, wherein a portion of the spacers overlies a portion of the silicide region;
a heavily doped source/drain region adjacent the LDS/LDD region; and
a stressor layer over the gate electrode, the sidewall spacers, and the silicide region.

11. The transistor of claim 10, wherein the transistor is a P-MOSFET and the stressor layer comprises a material having an intrinsic tensile stress.

12. The transistor of claim 11, wherein the stressor layer induces a first and a second stress in the substrate under the gate electrode, wherein the first stress is a compressive stress aligned substantially parallel to a surface of the substrate, and wherein the second stress is a tensile stress aligned substantially perpendicular to the surface of the substrate.

13. The transistor of claim 10, wherein the transistor is an N-MOSFET and the stressor layer comprises a material having an intrinsic compressive stress.

14. The transistor of claim 13, wherein the stressor layer induces a first and a second stress in the substrate under the gate electrode, wherein the first stress is a tensile stress aligned substantially parallel to a surface of the substrate, and wherein the second stress is a compressive stress aligned substantially perpendicular to the surface of the substrate.

15. The transistor of claim 10, wherein stressor layer comprises a material selected from the group consisting essentially of a silicon nitride, silicon carbide, silicon oxide, nitrided silicon oxide (SiON), silicon germanium, and combinations thereof.

16. A metal oxide semiconductor (MOS) transistor comprising:
a gate electrode on a substrate;
a pair of sidewall spacers along the gate electrode;
a dielectric layer on the sidewall spacers, wherein the dielectric layer comprises a material having a Poisson's ratio greater than about 0.25; and
a stressor layer on the dielectric layer.

17. The transistor of claim 16, wherein the stressor layer comprises a material having an intrinsic tensile stress.

18. The transistor of claim 17, wherein the stressor layer induces a first and a second stress in the substrate under the gate electrode, wherein the first stress is a compressive stress aligned substantially parallel to a surface of the substrate, and wherein the second stress is a tensile stress aligned substantially perpendicular to the surface of the substrate.

19. The transistor of claim 18, wherein the stressor layer comprises a material having an intrinsic compressive stress.

20. The transistor of claim 19, wherein the stressor layer induces a first and a second stress in the substrate under the gate electrode, wherein the first stress is a tensile stress aligned substantially parallel to a surface of the substrate, and wherein the second stress is a compressive stress aligned substantially perpendicular to the surface of the substrate.
